(19) United States
(12) Patent Application Publication
(10) Pub. No.: US 2024/0334760 A1
(43) Pub. Date: Oct. 3, 2024

(54) DISPLAY PANEL AND MANUFACTURING METHOD THEREFOR, AND DISPLAY DEVICE

(71) Applicants: Hefei Visionox Technology Co., Ltd., Hefei (CN); KunShan Go-Visionox Opto-Electronics Co., Ltd., Kunshan (CN)

(72) Inventors: Zhiwei ZHOU, Hefei (CN); Jinfang ZHANG, Hefei (CN); Lu ZHANG, Hefei (CN)

(73) Assignees: Hefei Visionox Technology Co., Ltd., Hefei (CN); KunShan Go-Visionox Opto-Electronics Co., Ltd., Kunshan (CN)

(21) Appl. No.: 18/654,283

(22) Filed: May 3, 2024

(30) Foreign Application Priority Data
Dec. 15, 2023 (CN) 202311739516.3

(51) Int. Cl. H10K 59/126; H10K 59/12; H10K 59/122; H10K 59/80

(52) U.S. Cl. CPC H10K 59/126; H10K 59/1201; H10K 59/122; H10K 59/873

(57) ABSTRACT

Disclosed are a display panel, a manufacturing method therefor, and a display device. The the display panel includes a substrate; a signal shielding layer, disposed on the substrate; a protection layer, disposed on the signal shielding layer; an isolation structure, disposed on the signal shielding layer and defined with a plurality of first isolation openings and a plurality of second isolation openings; and a light-emitting function layer, including a plurality of light-emitting devices. Orthogonal projections of the signal shielding layer and the protection layer on the substrate cover an orthogonal projection of the second isolation opening on the substrate separately. An area of the second isolation opening may serve as a light transmission hole area; and the signal shielding layer may effectively shield interference of a touch signal. Meanwhile, the signal shielding layer may be protected by the protection layer from damage thereby avoiding shielding failure and improving touch performance.

### CROSS-REFERENCE TO RELATED APPLICATION

This application claims priority to Chinese Patent Application No. 202311739516.3, filed on Dec. 15, 2023, which is hereby incorporated by reference in its entirety.

### TECHNICAL FIELD

The present disclosure relates to the field of display technologies, and in particular, to a display panel, a manufacturing method therefor, and a display device.

### BACKGROUND

With the development of touch technology and display technology, display panels have become increasingly popular. Taking common touch-based intelligent mobile terminals as an example, higher screen-to-body ratio design has brought users a better visual experience than before.

However, in practice, a problem of signal crosstalk is easy to occur for a display panel, resulting in poor touch performance.

### SUMMARY

In view of this, the present disclosure aims to provide a display panel, a manufacturing method therefor, and a display device to effectively reduce signal interference and improve touch performance.

In a first aspect, an embodiment of the present disclosure provides a display panel, including: a substrate; a signal shielding layer, disposed on the substrate; a protection layer, disposed on the signal shielding layer; an isolation structure, disposed on the signal shielding layer and defined with a plurality of first isolation openings and a plurality of second isolation openings; and a light-emitting function layer, including a plurality of light-emitting devices disposed in the first isolation openings; where an orthogonal projection of the signal shielding layer on the substrate covers an orthogonal projection of the plurality of second isolation openings on the substrate, and an orthogonal projection of the protection layer on the substrate covers the orthogonal projection of the plurality of second isolation openings on the substrate.

In a second aspect, an embodiment of the present disclosure provides a manufacturing method for a display panel, including: providing a substrate; forming a signal shielding layer and an inorganic material layer sequentially on the substrate; performing etching in the inorganic material layer to form an inorganic film layer; and forming an isolation structure on the inorganic film layer and performing etching in the inorganic film layer to form a protection layer, where a plurality of first isolation openings and a plurality of second isolation openings are formed in the isolation structure, the plurality of first isolation openings are configured to receive a plurality of light-emitting devices of a light-emitting function layer; an orthogonal projection of the signal shielding layer on the substrate covers an orthogonal projection of the plurality of second isolation openings on the substrate; and an orthogonal projection of the protection layer on the substrate covers the orthogonal projection of the plurality of second isolation openings on the substrate.

In a third aspect, an embodiment of the present disclosure provides a display device, including a display panel mentioned above in the first aspect of the embodiment of the present disclosure.

According to the technical solution provided by the present disclosure, the display panel includes a substrate, and a signal shielding layer, a protection layer, and an isolation structure sequentially disposed on the substrate; where a plurality of first isolation openings and a plurality of second isolation openings are formed in the isolation structure, and the plurality of first isolation openings are configured to receive a plurality of light-emitting devices of a light-emitting function layer; and an orthogonal projection of the signal shielding layer on the substrate covers an orthogonal projection of the plurality of second isolation openings on the substrate, and an orthogonal projection of the protection layer on the substrate covers the orthogonal projection of the plurality of second isolation openings on the substrate. In this way, an area where the second isolation opening is located may be used as a light transmission hole area; and the signal shielding layer may effectively shield interference of a touch signal caused by a touch electrode layer. Meanwhile, the signal shielding layer may be protected by the protection layer from damage during manufacturing process, so that shielding failure may be avoided and touch performance of the display panel may be effectively improved.

### BRIEF DESCRIPTION OF THE DRAWINGS

The above and other purposes, features and advantages of the present disclosure will become more apparent through a more detailed description of embodiments of the present disclosure with reference to accompanying drawings. The accompanying drawings are intended to provide a further understanding of the embodiments of the present disclosure and constitute a part of the description. They are used to explain the present disclosure together with the embodiments of the present disclosure, but do not constitute a limitation to the present disclosure. In the accompanying drawings, the same reference numeral generally represents the same part or step.

FIG. 1 is a schematic structural diagram of a display panel in the prior art.

FIG. 2 is a schematic diagram of a planar structure of a display panel according to an embodiment of the present disclosure.

FIG. 3 is a cross-sectional view of the display panel shown in FIG. 2 along AA′.

FIG. 4 is a schematic structural diagram of a display panel according to another embodiment of the present disclosure.

FIG. 5 is a schematic diagram of a planar structure of a display panel according to another embodiment of the present disclosure.

FIG. 6 is a schematic structural diagram of a display panel according to still another embodiment of the present disclosure.

FIG. 7 is a schematic structural diagram of a display panel according to yet still another embodiment of the present disclosure.

FIG. 8 is a schematic diagram of a planar structure of a display panel according to yet still another embodiment of the present disclosure.

FIG. 9 is a schematic structural diagram of a display panel according to yet still another embodiment of the present disclosure.

FIG. 10 is a schematic structural diagram of a display panel according to yet still another embodiment of the present disclosure.

FIG. 11 is a schematic structural diagram of a display panel according to yet still another embodiment of the present disclosure.

FIG. 12 is a flowchart of a manufacturing method for a display panel according to an embodiment of the present disclosure.

FIG. 13 is a schematic structural diagram of a display panel during manufacturing process according to an embodiment of the present disclosure.

FIG. 14 is a schematic structural diagram of a display panel during manufacturing process according to another embodiment of the present disclosure.

FIG. 15 is a schematic structural diagram of a display panel during manufacturing process according to still another embodiment of the present disclosure.

FIG. 16 is a schematic structural diagram of a display panel during manufacturing process according to yet still another embodiment of the present disclosure.

FIG. 17 is a schematic structural diagram of a display panel during manufacturing process according to yet still another embodiment of the present disclosure.

FIG. 18 is a schematic structural diagram of a display device according to an embodiment of the present disclosure.

FIG. 19 is a flowchart of a manufacturing method for a display panel according to another embodiment of the present disclosure.

FIG. 20 is a flowchart of a manufacturing method for a display panel according to still another embodiment of the present disclosure.

FIG. 21 is a flowchart of a manufacturing method for a display panel according to yet still another embodiment of the present disclosure.

### DETAILED DESCRIPTION OF THE EMBODIMENTS

Unless otherwise defined, technical or scientific terms used in the embodiments of the specification shall have usual meanings understood by those skilled in the art to which this specification belongs. Terms like “first”, “second”, and similar terms used in the embodiments of the specification do not indicate any order, quantity, or importance, but are merely used to avoid confusion among constituent elements.

Unless otherwise specified in the context, throughout the specification, term “plurality” indicates “at least two” and term “include” is interpreted as an open and inclusive term, meaning “including, but not limited to”. In the description of this specification, terms such as “an embodiment,” “some embodiments,” “exemplary embodiment,” “example,” “specific example,” and “some examples” are intended to indicate that specific features, structures, materials, or characteristics related to that embodiment or example are included in at least one embodiment or example of the specification. An illustrative representation of the above terms does not necessarily refer to the same embodiment or example.

Technical solutions in embodiments of the present disclosure will be clearly and completely described with reference to accompanying drawings corresponding to the embodiments of the present disclosure in the following description. Apparently, the described embodiments are only some, not all, embodiments of the present disclosure. Based on the embodiments in the present disclosure, all other embodiments obtained by those skilled in the art without creative efforts shall fall within the protection scope of the present disclosure.

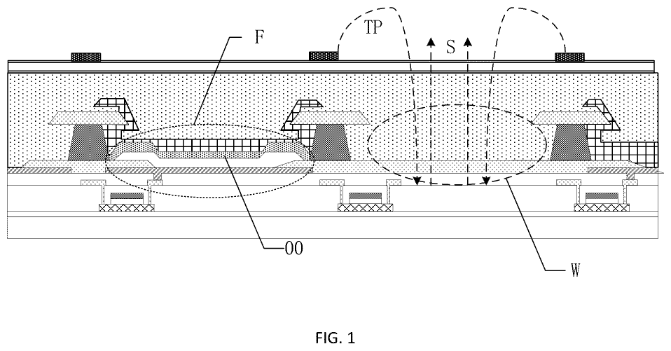

During a manufacturing process of a display panel, as shown in FIG. 1, light-emitting pixels F are encapsulated by using a pixel-level encapsulation scheme, that is, each light-emitting pixel F is independently packaged, resulting in spacing between the light-emitting pixels F. Meanwhile, cathodes 00 of the light-emitting pixels F may not cover gaps between the light-emitting pixels F. Due to requirements of screen fingerprint recognition and environmental light transmission, a hollow design is also required in a display area. Consequently, an opening W formed by punching may lead to crosstalk issues between an array signal S and a touch signal TP. When the crosstalk is severe, touch performance of the product may also be affected. Therefore, how to solve the issue of signal crosstalk has attracted much attention.

In this regard, the present disclosure provides a solution that may effectively reduce signal interference and improve touch performance by providing a signal shielding layer in an area corresponding to the opening, which may effectively shield touch signal interference caused by a touch electrode layer. Furthermore, by providing a protection film layer above the signal shielding layer, damage to the signal shielding layer caused by etching and other processes during manufacturing process may be effectively avoided, so that shielding failure may be avoided and the touch performance of the display panel may be effectively improved.

Patents PCT/CN2023/134518, 202310759370.2, 202310740412.8, and 202310707209.0 record relevant technical solutions of an isolation structure, and their contents are incorporated herein by reference in the present disclosure for reference.

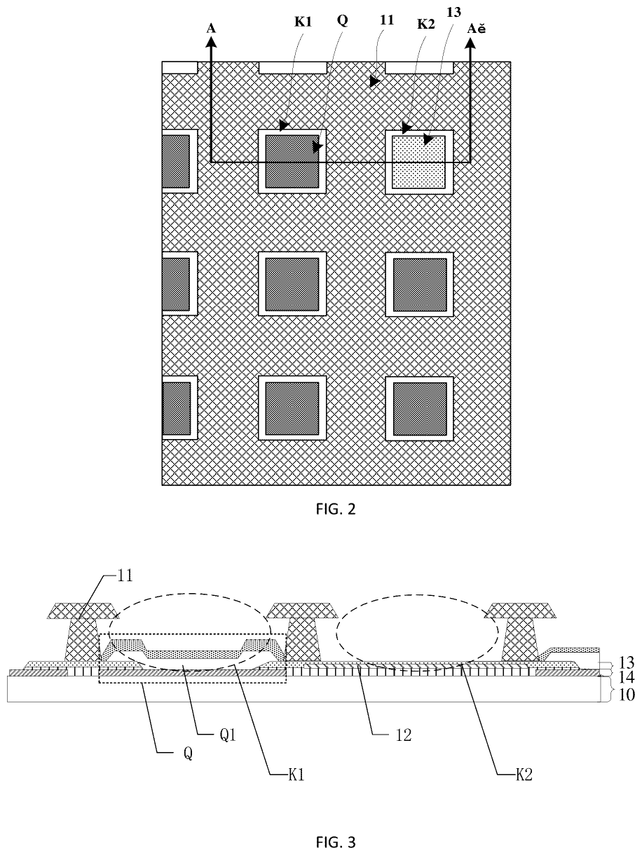

Specifically, as an optional implementation of the present disclosure, an embodiment of the present disclosure provides a display panel. FIG. 2 is a schematic diagram of a planar structure of a display panel according to an embodiment of the present disclosure. FIG. 3 is a cross-sectional view of the display panel shown in FIG. 2 along AA′. As shown in FIGS. 2 and 3, the display panel may at least include: a substrate 10, a signal shielding layer 12 located on the substrate 10, a protection layer 13 located on the signal shielding layer 12, and an isolation structure 11 located on the signal shielding layer 12.

The substrate 10 is mainly used for supporting and load-bearing. Specifically, the substrate 10 may be a rigid substrate such as a glass substrate or a silicon substrate, as well as a flexible substrate such as a stainless use steel (SUS) substrate or a polyimide (PI) substrate. That is to say, the display panel in this embodiment of the present disclosure may be a non-bendable rigid display panel or a bendable flexible display panel.

A plurality of first isolation openings K1 and a plurality of second isolation openings K2 are formed in the isolation structure 11, and the plurality of first isolation openings K1 are configured to receive a plurality of light-emitting devices Q of a light-emitting function layer Q1.

The quantities of the first isolation openings K1 and the second isolation openings K2 may be set according to actual requirements, and there is no specific limitation.

In this way, the isolation structure 11 may be used for isolating the light-emitting function layer Q1 of the plurality of light-emitting devices Q, thereby obtaining light-emitting pixels independent from each other. Moreover, the second isolation opening K2 may serve as a light transmission hole to provide a light transmission path for screen fingerprint recognition and environmental light transmission.

Correspondingly, an area where the second isolation opening K2 is located may serve as a light transmission hole area. To avoid crosstalk between touch signals and array signals caused by the presence of the light transmission hole area, an orthogonal projection of the signal shielding layer 12 on the substrate may be set to cover an orthogonal projection of the plurality of second isolation openings K2 on the substrate. In this way, not only the second isolation opening K2 may meet the requirement of light transmission, but also crosstalk between the touch signals and the array signals may be avoided due to the presence of the signal shielding layer 12. Furthermore, the signal shielding layer 12 also meets certain requirement of light transmission.

Meanwhile, it is found through research by inventors that in the manufacturing process of the display panel, formation of the isolation structure 11 requires two steps of etching process, including dry etching and wet etching. These two steps of the etching process may easily cause significant damage to the signal shielding layer 12, and lead to shielding function failure. Therefore, an orthogonal projection of the protection layer 13 on the substrate may be configured to cover the orthogonal projection of the plurality of second isolation openings K2 on the substrate. In this way, the protection layer 13 may be used for protecting the signal shielding layer 12, thereby avoiding damage caused by etching process in the manufacturing process of the display panel, ensuring a shielding effect of the signal shielding layer 12, and effectively improving the touch performance of the display panel.

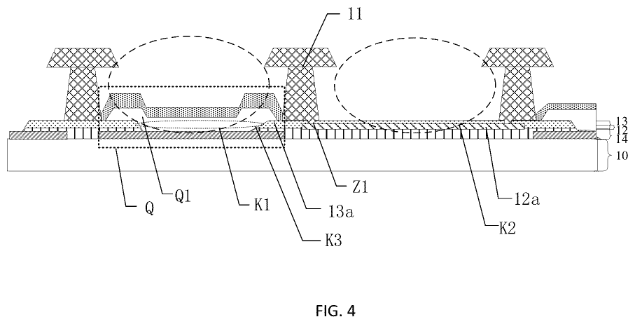

In some embodiments, as shown in FIG. 4, the protection layer 13 may include a protection portion 13a; and a plurality of first openings K3 are formed in the protection portion 13a.

The first opening K3 is communicated with the first isolation opening K1, and configured to receive the light-emitting device Q of the light-emitting function layer Q1.

The protection portion 13a is located on a side, away from the substrate 10, of the signal shielding layer 12, and an orthogonal projection of the protection portion 13a on the substrate 10 covers the orthogonal projection of the signal shielding layer 12 on the substrate 10.

It should be understood that the orthogonal projection of the protection portion 13a on the substrate 10 covers the orthogonal projection of the signal shielding layer 12 on the substrate 10, that is, the protection portion 13a covers the signal shielding layer 12, so that it may be avoided that the second isolation opening K2 exposes at least part of the signal shielding layer 12, thereby protecting the signal shielding layer 12. At the same time, punching holes (the first openings K3) on the protection layer 13 may ensure uniformity of thickness, in a direction perpendicular to the substrate 10, of the protection layer 13 in areas excluding the first openings K3, so that preparation complexity of the display panel may be reduced.

In some embodiments, the signal shielding layer 12 may include a plurality of signal shielding portions 12a arranged at intervals. The isolation structure 11 is electrically connected to the plurality of signal shielding portions 12a arranged at intervals, so that electrical connection between the plurality of signal shielding portions 12a may be achieved, thereby establishing a structural foundation for the signal shielding layer 12 to achieve a signal shielding effect.

It should be understood that due to the fact that the orthogonal projection of the signal shielding layer 12 on the substrate 10 covers the orthogonal projection of the plurality of second isolation openings K2 on the substrate 10, a signal shielding function for all the light transmission hole areas where the plurality of second isolation openings K2 are located may be achieved through electrical connection between the plurality of signal shielding portions 12a arranged at intervals by the isolation structure 11, thereby enhancing the signal shielding effect while improving the light transmittance.

To ensure the electrical connection between the isolation structure 11 and the signal shielding portions 12a, in some embodiments, as shown in FIG. 4, the protection portion 13a may include a plurality of first through holes Z1, and the isolation structure 11 is in contact with the signal shielding portions 12a through the first through hole Z1.

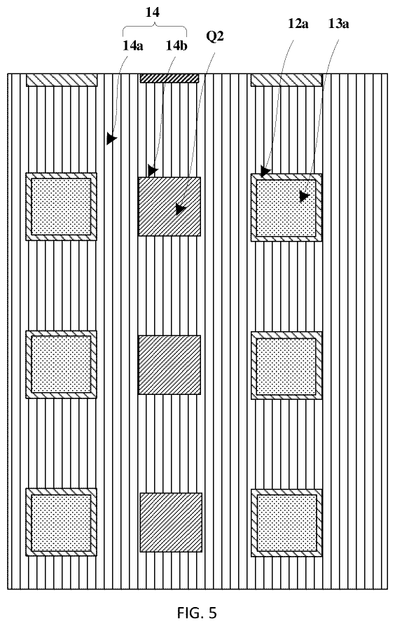

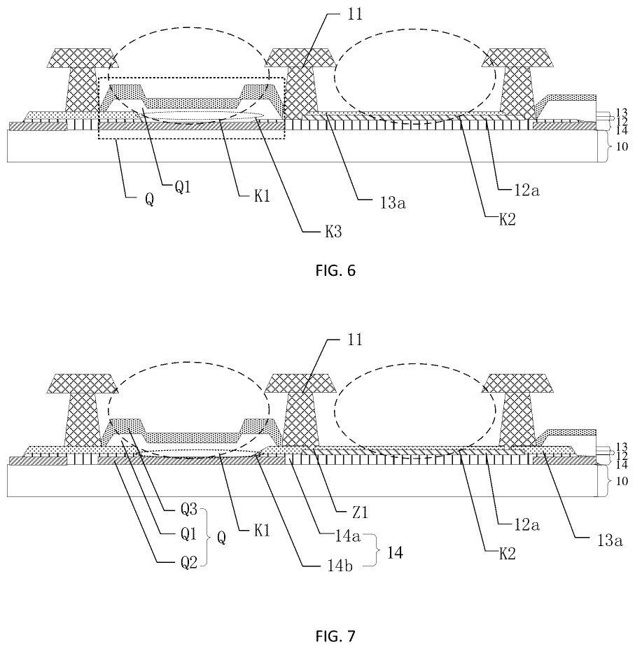

As it should be, the present disclosure is not limited to this. In some embodiments, as shown in FIGS. 5 and 6, the protection layer 13 may include a plurality of protection portions 13a arranged at intervals.

The signal shielding layer 12 may include a plurality of signal shielding portions 12a arranged at intervals, and the isolation structure 11 is electrically connected to the plurality of signal shielding portions 12a.

To avoid exposure of the signal shielding portion 12a by the second isolation opening K2, which leads to a risk of damage to the signal shielding portion 12a, the plurality of protection portions 13a arranged at intervals may be respectively disposed on a side, away from the substrate 10, of the plurality of signal shielding portion 12a arranged at intervals. In this way, each signal shielding portion 12a is equipped with a corresponding protection portion 13a on the side, away from the substrate 10, of the signal shielding portion 12a. An orthogonal projection of the protection portion 13a on the substrate 10 covers the orthogonal projection of the corresponding second isolation opening K2 on the substrate 10, thereby avoiding damage to the signal shielding portion 12a during the manufacturing process for the display panel.

In this embodiment, by setting the plurality of signal shielding portions 12a, signal shielding at different positions may be achieved according to signal shielding requirements at different positions. Compared to a signal shielding layer covering the entire surface, shielding materials may be save and preparation costs may be reduced.

Similarly, by setting the plurality of protection portions 13a, separate protection for the plurality of signal shielding portions 12a at different positions may be realized, thereby saving protection materials and further reducing preparation costs while ensuring the touch performance.

In specific implementation, as shown in FIG. 6, the orthogonal projection of the signal shielding portion 12a on the substrate 10 covers the orthogonal projection of the protection portion 13a on the substrate 10. A part of the signal shielding portion 12a is in direct contact with the isolation structure 11, and the orthogonal projection of the part of the signal shielding portion 12a on the substrate 10 extend beyond the orthogonal projection of the protection portion 13a on substrate 10.

In some embodiments, as shown in FIG. 4, the orthogonal projection of the protection portion 13a on the substrate 10 covers the orthogonal projection of the signal shielding portion 12a on the substrate. The protection portion 13a includes a first through hole Z1, and the isolation structure 11 is in contact with the signal shielding portion 12a through the first through hole Z1.

In some embodiments, as shown in FIG. 7, the display panel may further include a first insulation layer 14 located on a side, close to the substrate 10, of the signal shielding layer 12. The first insulation layer 14 may include an insulation portion 14a and a plurality of pixel openings 14b formed in the insulation portion 14a. The material of the insulation portion 14a may be an organic insulation material or an inorganic insulation material.

During the implementation, the pixel opening 14b may be communicated with the first isolation opening K1 to receive the light-emitting devices Q of the light-emitting function layer Q1. Specifically, through the pixel opening 14b, a position of the light-emitting layer in the light-emitting function layer Q1 may be better defined.

In some embodiments, as shown in FIG. 7, the light-emitting device Q may further include a first electrode Q2 located on the side, close to the substrate 10, of the light-emitting function layer Q1. The pixel opening 14b exposes at least a part of the first electrode Q2.

Insulation characteristics of the first insulation layer 14 may insulate the first electrode Q2 from the isolation structure 11. Moreover, since an area of the first electrode Q2 in the light-emitting device Q exposed by the pixel opening 14b is a light-emitting area of the light-emitting device Q, it is possible to better limit the light-emitting area through the pixel opening 14b of the first insulation layer 14.

In actual application, the first insulation layer 14 includes a pixel definition layer.

It should be explained that arrangement of the first insulation layer 14 and the protection layer 13 may be achieved through a same punching process, so that there is no need to use a new mask during the manufacturing process, thereby saving preparation costs, simplifying the manufacturing process, and improving preparation efficiency.

In some implementations, still as shown in FIG. 7, the light-emitting device Q may further include a second electrode Q3 located on the side, away from the substrate 10, of the light-emitting function layer Q1. The second electrode Q3 is located in the first isolation opening K1, and is in contact with a side wall of the isolation structure 11.

Specifically, the light-emitting function layer Q1 may include a hole injection layer, a hole transport layer, a light-emitting layer, an electron transport layer, and an electron injection layer sequentially stacked on a side, away from the substrate 10, of the first electrode Q2. The second electrode Q3 is provided on a side, away from the substrate, of the electron injection layer.

The light-emitting layer may include materials with electroluminescence (EL) properties (hereinafter referred to as light-emitting material). The first electrode, also known as an anode, is used to provide holes to the light-emitting layer; and the second electrode, also known as a cathode, is used to provide electrons to the light-emitting layer. The holes provided by the first electrode and the electrons provided by the second electrode may recombine in the light-emitting layer and excite the light-emitting material in the light-emitting layer to emit light. The hole injection layer and the hole transport layer may be made of materials with high hole mobility, so that the holes provided by the first electrode may be better transferred to the light-emitting layer. Similarly, the electron injection layer and the electron transport layer may be made of materials with high electron mobility, so that the electrons provided by the second electrode may be better transferred to the light-emitting layer.

It should be noted that the second electrode Q3 is in contact with the isolation structure 11, that is, the signal shielding layer 12 is electrically connected to the second electrode Q3 through the isolation structure 11. Therefore, the signal shielding layer 12, the isolation structure 11, and the second electrode Q3 may form a full potential layer for signal shielding.

An area corresponding to the first isolation opening K1 is shielded by the second electrode Q3, and an area corresponding to the second isolation opening K2 is shielded by the signal shielding layer 12, thereby avoiding signal crosstalk and improving touch performance.

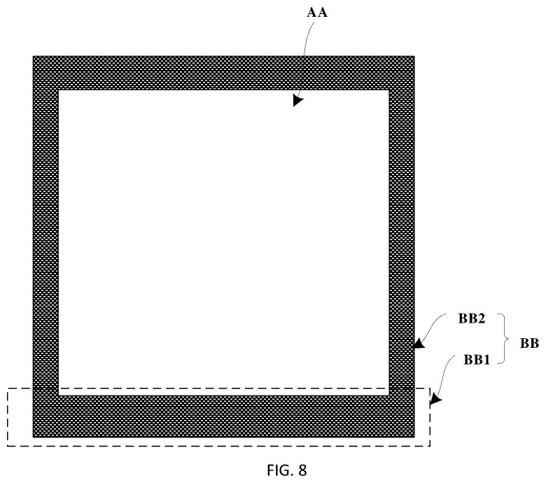

In some embodiments, as shown in FIG. 8, the display panel may include a display area AA and a frame area BB surrounding the display area AA. The frame area BB may include a lower frame area BB1. During the implementation, the lower frame area BB1 may refer to an area closest to a binding area in the frame area BB.

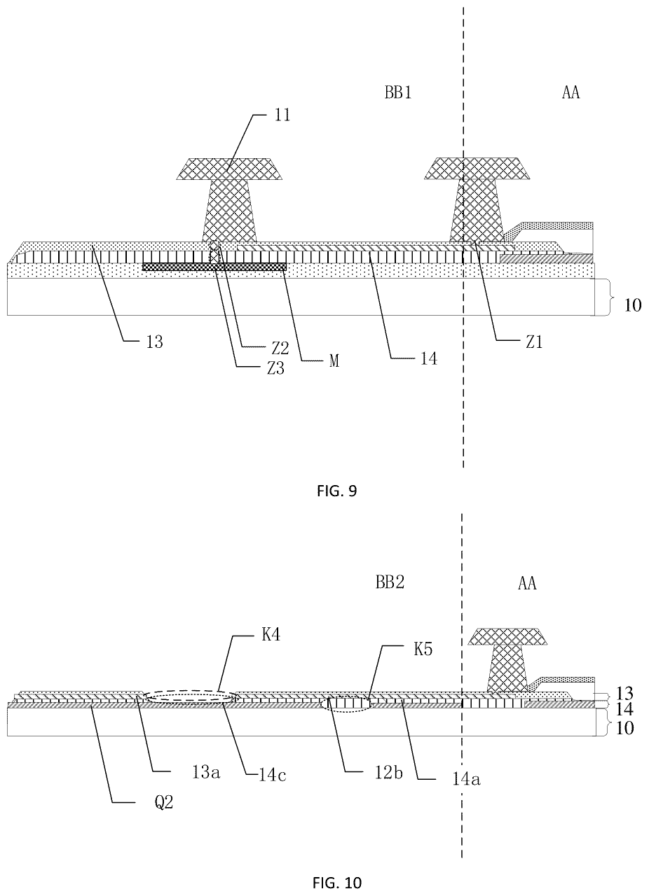

As shown in FIG. 9, the isolation structure 11 is located in the display area AA and at least a part of the lower frame area BB1.

The protection layer 13 located in the lower frame area BB1 may further include a second through hole Z2. The first insulation layer 14 located in the lower frame area BB1 may include a third through hole Z3, and the second through hole Z2 is communicated with the third through hole Z3. The isolation structure 11 located in the lower frame area BB1 is in contact with a grounding terminal M through the second through hole Z2 and the third through hole Z3.

The grounding terminal M may be a metal layer connected to a grounding signal. The metal layer is located on a side, close to the substrate 10, of the first insulation layer 14, and its specific position may be set according to actual requirements. For example, it may be disposed between a first planarization layer and a second planarization layer.

The isolation structure 11 is in contact with the grounding terminal M, so that the isolation structure 11 may be connected to the ground signal, thereby achieving signal shielding functions of the isolation structure 11, the second electrode Q3 connected to the isolation structure 11, and the signal shielding layer 12 connected to the isolation structure 11.

In some embodiments, as shown in FIG. 8, the frame area BB may further include a second frame area BB12 excluding the lower frame area BB1. To ensure reliability of the display panel, the isolation structure 11 is usually not disposed in the second frame area BB12. Therefore, a signal shielding structure covering the entire second frame area BB132 may not be constructed in the second frame area BB2 through the isolation structure 11.

To ensure a good signal shielding effect in the second frame area BB2, as shown in FIG. 10, the signal shielding layer 12 may further include a shielding structure 12b located in the second frame area BB2, and a plurality of shielding openings K4 formed in the shielding structure 12b.

To avoid the problem of signal crosstalk in an area corresponding to the shielding opening K4, an orthogonal projection of the shielding structure 12b and the first electrode Q2 located in the second frame area BB2 on the substrate 10 covers an orthogonal projection of the second frame area BB2 on the substrate 10. In this way, a signal shielding structure covering the second frame area BB2 may be formed by the shielding structure 12b and the first electrode Q2, thereby achieving the signal shielding function of the second frame area BB2.

In some embodiments, the insulation portion 14a located in the second frame area BB2 may further include a plurality of insulation openings 14c, and the plurality of shielding openings K4 is communicated with the plurality of insulation openings 14c located in the second frame area BB2 to expose the first electrode Q2 located in the second frame area BB2.

During the implementation, the orthogonal projection of the shielding structure 12b and the plurality of shielding openings k4 on the substrate 10 may cover the orthogonal projection of the second frame area BB2 on the substrate 10. Specifically, signal shielding for the corresponding area may be achieved by the shielding structure 12b. Meanwhile, the plurality of shielding openings K4 may be used to release water vapor inside the display panel, thereby improving the performance of the display panel.

Specifically, the first electrode Q2 located in the second frame area BB2 is in contact with the grounding terminal, thereby enabling signal shielding function of the first electrode Q2 located in the second frame area BB2.

As shown in FIG. 10, the shielding structure 12b located in the second frame area BB2 may extend into the display area AA and be electrically connected to the isolation structure 11.

Specifically, a part, close to the second frame area BB1, of the isolation structure 11 may be in contact with the shielding structure 12b through the first through hole Z1 of the protection portion 13a, thereby achieving the signal shielding function of the shielding structure 12b.

In some embodiments, still as shown in FIG. 10, a plurality of electrode openings K5 are formed in the first electrode Q2 located in the second frame area BB2, and the first insulation layer 14 located in the second frame area BB2 fills the plurality of electrode openings K5. An orthogonal projection of the shielding structure 12b on the substrate 10 covers an orthogonal projection of the plurality of electrode openings K5 on the substrate. 10.

During the implementation, the first electrode Q2 located in the second frame area BB2 may be a full-area electrode that covers the second frame area BB2. The electrode opening K5 provided therein may be used to release water vapor in the organic film layer of the display panel. Meanwhile, the orthogonal projection of the shielding structure 12b on the substrate 10 covers the orthogonal projection of the plurality of electrode openings K5 on the substrate 10, so that the problem of signal crosstalk in the area corresponding to the electrode openings K5 may be avoided. In this way, comprehensive signal shielding of the second frame area BB2 may be achieved through staggered punching on the two metal film layers, namely the shielding structure 12b and the first electrode Q2 in the second frame area BB2, so that the problem of signal crosstalk may be avoided.

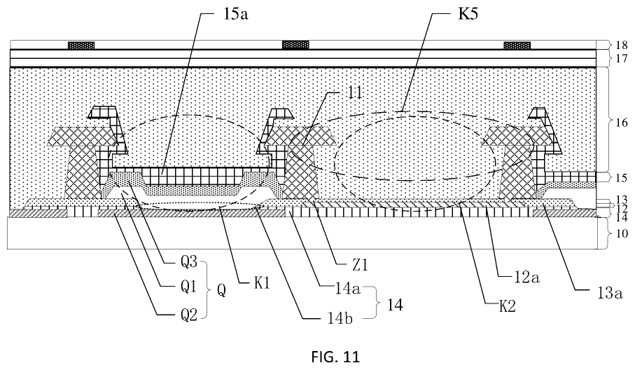

In some embodiments, as shown in FIG. 11, the display panel may further include a first encapsulation layer 15 located on a side, away from the substrate 10, of the second electrode Q3, and a second encapsulation layer 16 located on a side, away from the substrate 10, of the first encapsulation layer 15.

The first encapsulation layer 15 may include a first encapsulation portion 15a and a plurality of second openings K5 formed in the first encapsulation portion 15a. An orthogonal projection of the first encapsulation portion 15a on the substrate 10 covers an orthogonal projection of the second electrode Q3 on the substrate 10. In this way, independent encapsulation of each light-emitting pixel may be achieved through the first encapsulation portion 15a.

During actual application, the first encapsulation portion 15a may be formed through combination of chemical vapor deposition (CVD) and etching. A material of the first encapsulation portion 15a may be an inorganic insulation material.

As it should be, the present disclosure is not limited to this. In some other embodiments, the material of the first encapsulation layer 15 may also be an organic insulation material. Specifically, it can be set according to actual encapsulation requirements and technical requirements.

Still as shown in FIG. 11, the second opening K5 is communicated with the second isolation opening K2. An orthogonal projection of the second opening K5 on substrate 10 covers the orthogonal projection of the second isolation opening K2 on substrate 10. In this way, the second opening K5 exposes the second isolation opening K2, thereby exposing at least a part of the protection layer 13.

The orthogonal projection of the second encapsulation layer 16 on the substrate 10 covers the substrate 10, that is, the second encapsulation layer 16 not only covers the first encapsulation portion 15a, but also covers the second opening K5.

Specifically, the second encapsulation layer 16 may be an organic encapsulation film formed by ink-jet printing.

It should be noted that the organic encapsulation film is prone to peeling when in contact with the metal, that is, the organic encapsulation film is prone to peeling when in contact with the signal shielding layer 12. In the embodiment of the present disclosure, the protection layer 13 may isolate a direct contact between the organic encapsulation film and the signal shielding layer 12 in the second isolation opening K2, so that the possibility of organic encapsulation film peeling may be reduced and effectiveness of encapsulation may be improved.

In some embodiments, as shown in FIG. 11, the display panel may further include a third encapsulation layer 17 located on a side, away from the substrate, of the second encapsulation layer 16. An orthogonal projection of the third encapsulation layer 17 on the substrate 10 covers the substrate 10.

During factual application, the first encapsulation layer 15 and the third encapsulation layer 17 may be prepared by inorganic materials, while the second encapsulation layer 16 may be prepared by organic materials. The second encapsulation layer 16 prepared by organic materials is located between the first encapsulation layer 15 and the third encapsulation layer 17 prepared by the inorganic materials, so that a encapsulation structure may be formed, thereby better isolating water and oxygen and achieving an encapsulation effect.

To achieve the touch function of the display panel, as shown in FIG. 11, the display panel may further include a touch electrode layer 18 located on a side, away from the substrate 10, of the encapsulation structure.

In some embodiments, the display panel may include a display area and a non-display area.

The protection layer 13 is provided with a second through hole in the non-display area.

The first insulation layer 14 is provided with a third through hole in the non-display area, and the second through hole is communicated with the third through hole. The isolation structure 11 is in contact with the grounding terminal through the second through hole and the third through hole, so that the shielding effect of the signal shielding layer 12 in contact with the isolation structure 11 may be ensured.

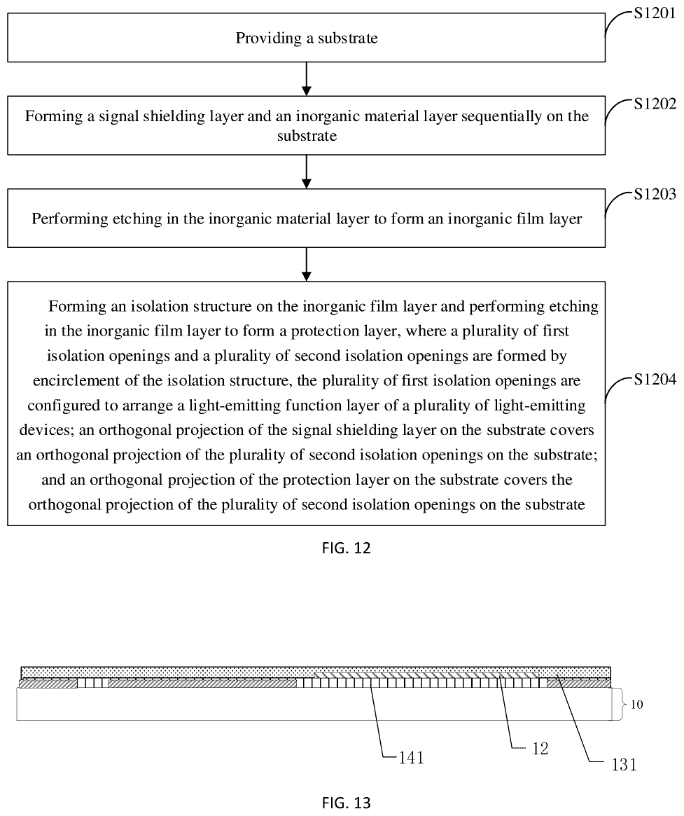

As another optional implementation of the present disclosure, a manufacturing method for a display panel is provided. As shown in FIG. 12, the manufacturing method for the display panel includes the following steps.

S1201: providing a substrate.

S1202: forming a signal shielding layer and an inorganic material layer sequentially on the substrate.

S1203: performing etching in the inorganic material layer to form an inorganic film layer.

S1204: forming an isolation structure on the inorganic film layer and performing etching in the inorganic film layer to form a protection layer, where a plurality of first isolation openings and a plurality of second isolation openings are formed in the isolation structure, the plurality of first isolation openings are configured to receive a plurality of light-emitting devices of a light-emitting function layer; an orthogonal projection of the signal shielding layer on the substrate covers an orthogonal projection of the plurality of second isolation openings on the substrate; and an orthogonal projection of the protection layer on the substrate covers the orthogonal projection of the plurality of second isolation openings on the substrate.

The display panel prepared according to the embodiment of the present disclosure includes a substrate; a signal shielding layer, disposed on the substrate; a protection layer, disposed on the signal shielding layer; an isolation structure, disposed on the signal shielding layer and defined with a plurality of first isolation openings and a plurality of second isolation openings; and a light-emitting function layer, including a plurality of light-emitting devices disposed in the first isolation openings; where an orthogonal projection of the signal shielding layer on the substrate covers an orthogonal projection of the plurality of second isolation openings on the substrate, and an orthogonal projection of the protection layer on the substrate covers the orthogonal projection of the plurality of second isolation openings on the substrate.

In this way, an area where the second isolation opening is located may be used as a light transmission hole area; and the signal shielding layer may effectively shield interference of a touch signal caused by a touch electrode layer. Meanwhile, the signal shielding layer may be protected by the protection layer from damage during manufacturing process, so that shielding failure may be avoided and touch performance of the display panel may be effectively improved.

In some embodiments, as shown in FIG. 19, the step S1202 may further include the following steps.

S12021: forming an insulation material layer on the substrate.

S12022: sequentially forming the signal shielding layer and the inorganic material layer on the insulation material layer.

Specifically, as shown in FIG. 13, after the insulation material layer 141 on the substrate 10 is formed, the metal material layer may be prepared on the insulation material layer, and the signal shielding layer 12 may be formed through patterned processing on the metal material layer, and then the inorganic material layer 131 may be formed on the signal shielding layer 12.

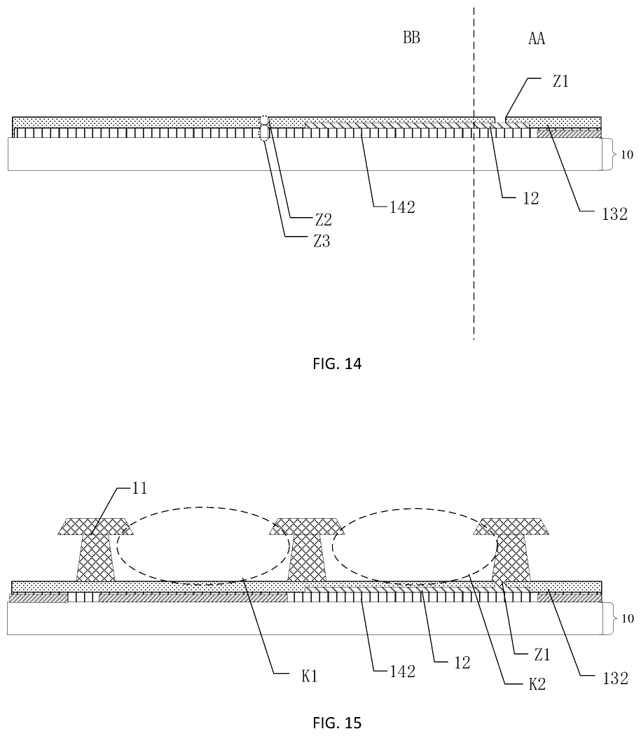

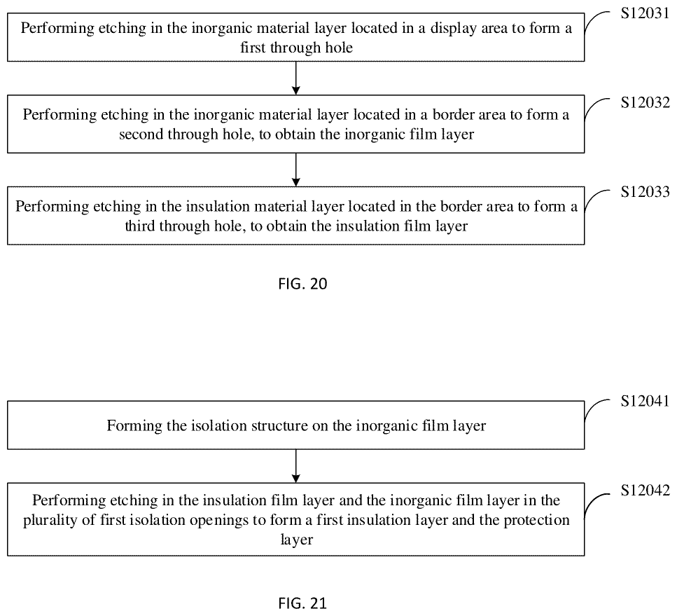

Correspondingly, the step S1203 mentioned above, as shown in FIG. 14 and FIG. 20, may include the following steps.

S12031: performing etching in the inorganic material layer located in a display area to form a first through hole.

S12032: performing etching in the inorganic material layer located in a frame area to form a second through hole, to obtain the inorganic film layer.

S12033: performing etching in the insulation material layer located in the frame area to form a third through hole, to obtain the insulation film layer.

As shown in FIG. 14, the inorganic material layer 131 in the display area AA may be etched to form a first through hole Z1; the inorganic material layer 131 in the frame area BB may be etched to form a second through hole Z2, and the inorganic film layer 132 is formed.

The insulation material layer 141 in the frame area may be etched to form a third through hole Z3, and the insulation film layer 142 is formed. And the second through hole is communicated with the third through hole.

The frame area BB includes a lower frame area. Correspondingly, the step S1204 above, as shown in FIG. 15 and FIG. 21, may include the following steps.

S12041: forming the isolation structure on the inorganic film layer.

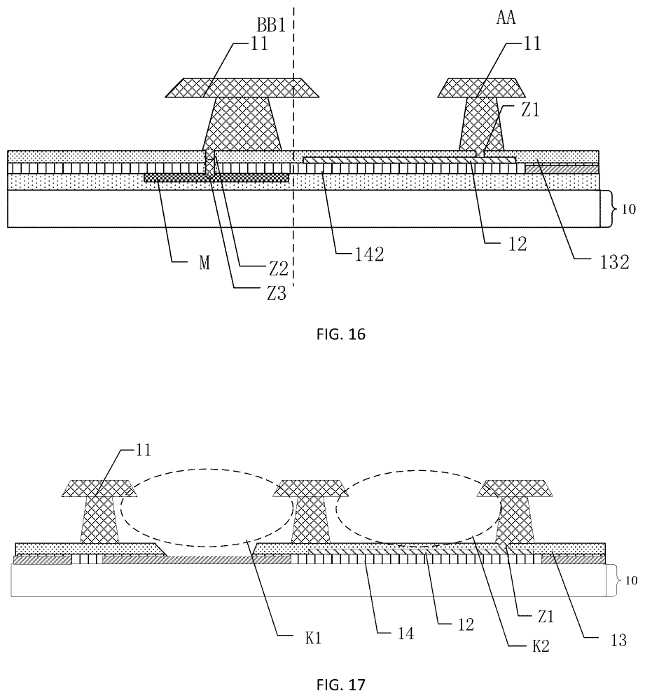

As shown in FIG. 15, the isolation structure 11 may be formed on the inorganic film layer 132. The isolation structure 11 located in the display area is in contact with the signal shielding layer 12 through the first through hole Z1; as shown in FIG. 16, the isolation structure 11 located in the lower frame area BB1 is in contact with the grounding terminal M through the second through hole Z2 and the third through hole Z3.

S12042: performing etching in the insulation film layer and the inorganic film layer in the plurality of first isolation openings to form a first insulation layer and the protection layer.

As shown in FIG. 17, the insulation film layer 142 and the inorganic film layer 132 in the first isolation opening K1 are etched to form the first insulation layer 14 and the protection layer 13.

The first insulation layer may include a pixel definition layer.

In the embodiment of the present disclosure, after the insulation material layer is formed, the signal shielding layer and the inorganic material layer are then added, so that the first insulation layer and the protection layer may be formed separately through a same etching process. And there is no need to use a new mask for preparing the protection layer, thereby saving preparation costs, simplifying the manufacturing process, and improving preparation efficiency. Meanwhile, the touch performance of the display panel may be improved and the product yield may be increased through the setting of the signal shielding layer and the protection layer.

The layer structures and corresponding explanations of the display panel obtained by the manufacturing method may be obtained by referring to the corresponding descriptions in the display panel as described above.

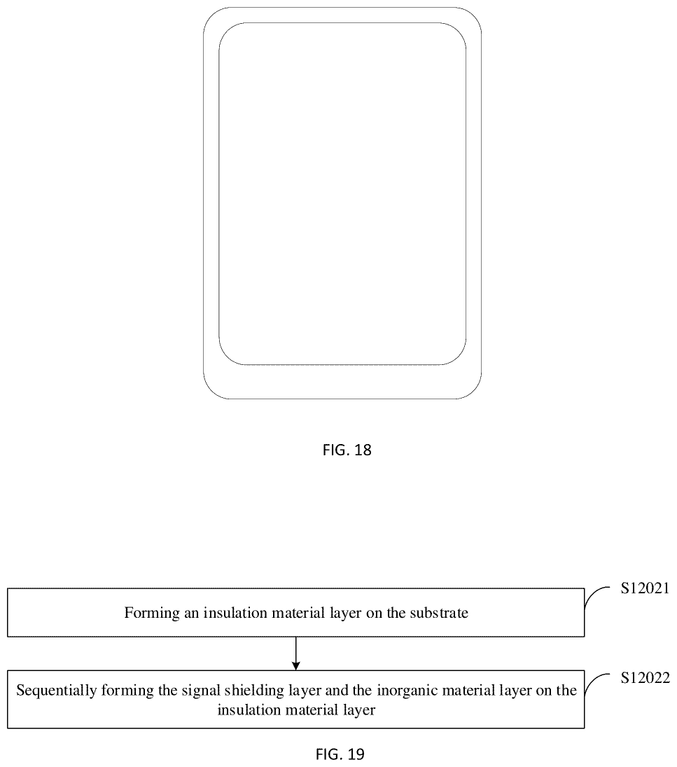

As another optional implementation of the present disclosure, a display device is provided. The display device includes a display panel provided in any embodiment mentioned above. As shown in FIG. 18, FIG. 18 is a schematic structural diagram of a display device according to an embodiment of the present disclosure, the display device may be a smart phone, a tablet, a digital camera and so on, and details are not described herein again.

The various embodiments in this specification are described in a progressive manner, with each embodiment focusing on the differences from other embodiments. Similarities and commonalities among the embodiments may be referenced mutually.

The above description of the disclosed embodiments enables those skilled in the art to implement or use the present disclosure. Multiple modifications to these embodiments will be apparent to those skilled in the art. The general principles defined in the present disclosure can be implemented in other embodiments without departing from the spirit or scope of the present disclosure. Therefore, the present disclosure will not be limited to the embodiments shown here, but will conform to the broadest scope consistent with the principles and novel features disclosed in the present disclosure.

What is claimed is:

1. A display panel, comprising:
a substrate;
a signal shielding layer, disposed on the substrate;
a protection layer, disposed on the signal shielding layer;
an isolation structure, disposed on the signal shielding layer and defined with a plurality of first isolation openings and a plurality of second isolation openings; and
a light-emitting function layer, comprising a plurality of light-emitting devices disposed in the first isolation openings;
wherein an orthogonal projection of the signal shielding layer on the substrate covers an orthogonal projection of the plurality of second isolation openings on the substrate, and an orthogonal projection of the protection layer on the substrate covers the orthogonal projection of the plurality of second isolation openings on the substrate.

2. The display panel according to claim 1, wherein the protection layer comprises a protection portion;
a plurality of first openings are formed in the protection portion;
the plurality of first openings are communicated with the plurality of first isolation openings correspondingly, and configured to receive the light-emitting function layer; and
the protection portion is located on a side, away from the substrate, of the signal shielding layer, and an orthogonal projection of the protection portion on the substrate covers the orthogonal projection of the signal shielding layer on the substrate.

3. The display panel according to claim 2, wherein the signal shielding layer comprises a plurality of signal shielding portions arranged at intervals; and
the isolation structure is electrically connected to the plurality of signal shielding portions.

4. The display panel according to claim 3, wherein the protection portion comprises a plurality of first through holes; and
the isolation structure is in contact with the signal shielding portion through the first through hole.

5. The display panel according to claim 1, wherein the protection layer comprises a plurality of protection portions arranged at intervals;
the signal shielding layer comprises a plurality of signal shielding portions arranged at intervals, and the isolation structure is electrically connected to the plurality of signal shielding portions; and
the plurality of protection portions arranged at intervals are located respectively on a side, away from the substrate, of the plurality of signal shielding portions arranged at intervals.

6. The display panel according to claim 5, wherein an orthogonal projection of the signal shielding portion on the substrate covers an orthogonal projection of the protection portion on the substrate; a part of the signal shielding portion is in direct contact with the isolation structure, and the orthogonal projection of the part of the signal shielding portion on the substrate extend beyond the orthogonal projection of the protection portion on the substrate.

7. The display panel according to claim 5, wherein an orthogonal projection of the protection portion on the substrate covers an orthogonal projection of the signal shielding portion on the substrate, the protection portion comprises a first through hole, and the isolation structure is in contact with the signal shielding portion through the first through hole.

8. The display panel according to claim 1, further comprising a first insulation layer located on a side, close to the substrate, of the signal shielding layer; wherein the first insulation layer comprises an insulation portion and a plurality of pixel openings formed in the insulation portion;
the plurality of pixel openings are communicated with the plurality of first isolation openings correspondingly, and are configured to receive the light-emitting device of the light-emitting function layer;
the light-emitting device further comprises a first electrode located on a side, close to the substrate, of the light-emitting function layer and the pixel opening exposes at least a part of the first electrode; and
the first insulation layer comprises a pixel definition layer.

9. The display panel according to claim 8, further comprising a display area and a frame area surrounding the display area;
wherein the frame area comprises a lower frame area;
the isolation structure is located in the display area and at least a part of the lower frame area;
the protection layer located in the lower frame area further comprises a second through hole, the first insulation layer located in the lower frame area comprises a third through hole, the second through hole is communicated with the third through hole; and
the isolation structure located in the lower frame area is in contact with a grounding terminal through the second through hole and the third through hole.

10. The display panel according to claim 9, wherein the frame area further comprises a second frame area excluding the lower frame area; and
the signal shielding layer further comprises a shielding structure located in the second frame area; a plurality of shielding openings is formed in the shielding structure; and an orthogonal projection of the shielding structure located in the second frame area and an orthogonal projection of the first electrode located in the second frame area on the substrate cover an orthogonal projection of the second frame area on the substrate.

11. The display panel according to claim 10, wherein the insulation portion located in the second frame area further comprises a plurality of insulation openings; and
the plurality of shielding openings are communicated with the plurality of insulation openings correspondingly to expose the first electrode located in the second frame area.

12. The display panel according to claim 10, wherein a plurality of electrode openings are formed in the first electrode located in the second frame area; and the first insulation layer located in the second frame area fills the plurality of electrode openings; and
the orthogonal projection of the shielding structure on the substrate covers an orthogonal projection of the plurality of electrode openings on the substrate.

13. The display panel according to claim 10, wherein the first electrode located in the second frame area is in contact with the grounding terminal; and
the shielding structure extends to the display area and is electrically connected to the isolation structure.

14. The display panel according to claim 1, wherein the light-emitting device further comprises a second electrode located on a side, away from the substrate, of the light-emitting function layer; and the second electrode is located in the first isolation opening and is in contact with a side wall of the isolation structure.

15. The display panel according to claim 14, further comprising a first encapsulation layer located on a side, away from the substrate, of the second electrode, and a second encapsulation layer located on a side, away from the substrate, of the first encapsulation layer;
wherein the first encapsulation layer comprises a first encapsulation portion and a plurality of second openings formed in the first encapsulation portion; an orthogonal projection of the first encapsulation portion on the substrate covers an orthogonal projection of the second electrode on the substrate; the second opening is communicated with the second isolation opening; and an orthogonal projection of the second opening on the substrate covers the orthogonal projection of the second isolation opening on the substrate; and
an orthogonal projection of the second encapsulation layer on the substrate covers the substrate.

16. A manufacturing method for the display panel according to claim 1, comprising:
providing a substrate;
forming a signal shielding layer and an inorganic material layer sequentially on the substrate;
performing etching in the inorganic material layer to form an inorganic film layer; and
forming an isolation structure on the inorganic film layer and performing etching in the inorganic film layer to form a protection layer, wherein a plurality of first isolation openings and a plurality of second isolation openings are formed in the isolation structure, the plurality of first isolation openings are configured to receive a plurality of light-emitting devices of a light-emitting function layer; an orthogonal projection of the signal shielding layer on the substrate covers an orthogonal projection of the plurality of second isolation openings on the substrate; and an orthogonal projection of the protection layer on the substrate covers the orthogonal projection of the plurality of second isolation openings on the substrate.

17. The method according to claim 16, wherein the forming a signal shielding layer and an inorganic material layer sequentially on the substrate comprises:
forming an insulation material layer on the substrate; and
sequentially forming the signal shielding layer and the inorganic material layer on the insulation material layer.

18. The method according to claim 17, wherein the performing etching in the inorganic material layer to form an inorganic film layer comprises:
performing etching in the inorganic material layer located in a display area to form a first through hole;
performing etching in the inorganic material layer located in a frame area to form a second through hole, to obtain the inorganic film layer; and
performing etching in the insulation material layer located in the frame area to form a third through hole, to obtain the insulation film layer, wherein the second through hole is communicated with the third through hole.

19. The method according to claim 18, wherein the frame area comprises a lower frame area; and
the forming an isolation structure on the inorganic film layer and performing etching in the inorganic film layer to form a protection layer comprises:
forming the isolation structure on the inorganic film layer, wherein the isolation structure located in the display area is in contact with the signal shielding layer through the first through hole; and the isolation structure located in the lower frame area is in contact with a grounding terminal through the second through hole and the third through hole; and
performing etching in the insulation film layer and the inorganic film layer in the plurality of first isolation openings to form a first insulation layer and the protection layer.

20. A display device, comprising a display panel according to claim 1.
